(19) United States
(12) Patent Application Publication
(10) Pub. No.: US 2014/0175655 A1
(43) Pub. Date: Jun. 26, 2014

(54) CHIP BONDING STRUCTURE AND MANUFACTURING METHOD THEREOF

(71) Applicant: Industrial Technology Research Institute, Hsinchu (TW)

(72) Inventors: Jui-Chin Chen, Hsinchu County (TW); Cha-Hsin Lin, Miaoli County (TW); Tzu-Kun Ku, Hsinchu City (TW)

(21) Appl. No.: 13/911,075

(22) Filed: Jun. 6, 2013

(30) Foreign Application Priority Data
Dec. 22, 2012 (TW) 101149286

(51) Int. Cl. H01L 23/00

(52) U.S. Cl. CPC H01L 24/29; H01L 24/83
USPC 257/762; 228/165; 228/172

(57) ABSTRACT

A chip bonding structure at least includes a first substrate, a second substrate opposite to the first substrate, and a copper bonding structure sandwiched in between the first and the second substrates. A Cu—Cu bonding interface is within the copper bonding structure and is characterized with combinations of protrusions and recesses, and the copper crystallization orientation at one side of the Cu—Cu bonding interface is different from that at another side.

### CROSS-REFERENCE TO RELATED APPLICATION

This application claims the priority benefit of Taiwan application serial no. 101149286, filed on Dec. 22, 2012. The entirety of the above-mentioned patent application is hereby incorporated by reference herein and made a part of this specification.

### TECHNICAL FIELD

The technical field relates to a chip bonding structure and a manufacturing method thereof.

### BACKGROUND

In a wafer level direct bonding process, the preprocessing usually comprises chemical mechanical polishing (CMP) and the bonding process, for example, comprises a Cu—Cu bond, an oxide-oxide fusion bond, or a Cu-oxide hybrid bond. During the bonding of wafer surfaces, the surface topography (or surface flatness), surface roughness, and surface cleanness are three interested factors at present.

For example, in the case of a Cu-oxide hybrid bond, an effective solution still needs to be found for the dishing problem of a copper bond pad after CMP. The larger the size of a copper bond pad becomes, the more serious the dishing problem of copper bond pad becomes. Thus, the copper bond pad might fail to be bonded due to the dishing problem.

### SUMMARY

One of exemplary embodiments comprises a chip bonding structure. The chip bonding structure at least comprises a first substrate, a second substrate opposite to the first substrate, and a copper bonding structure sandwiched in between the first and the second substrates. A Cu—Cu bonding interface is within the copper bonding structure and is characterized with combinations of protrusions and recesses, and the copper crystallization orientation at one side of the Cu—Cu bonding interface is different from that at another side of the Cu—Cu bonding interface.

Another of exemplary embodiments comprises a hybrid chip bonding method. The method is used for bonding a first substrate and a second substrate. A first oxide layer is formed on a surface of the first substrate, and a first copper layer is disposed within the first oxide layer. A second oxide layer is formed on a surface of the second substrate, and a second copper layer is disposed within the second oxide layer. Moreover, the first copper layer and the second copper layer are formed through a copper damascene process. In the hybrid chip bonding method, a first copper chemical mechanical polishing (CMP) process is performed on the first copper layer, and a second copper CMP process is performing on the second copper layer, such that excess copper at the top surfaces of the first copper layer and the second copper layer is respectively removed to form dishing concaves. Thereafter, a part of the first oxide layer is removed to protrude the top surface of the first copper layer from the first oxide layer, and a non-metal or barrier CMP process is then performed on the top surface of the first copper layer protruding from the first oxide layer to turn the top surface into a convex. The non-metal or barrier CMP process is a copper passivation process. The dishing concave of the second copper layer is connected to the convex of the first copper layer to make the first and second oxide layers contact each other, and an annealing is performed to bond the first and second oxide layers via a covalent bond formed therebetween and at the same time bond the first copper layer and the second copper layer.

Yet another of exemplary embodiments comprises a thermocompression chip bonding method. The method is used for bonding a first substrate and a second substrate. A first oxide layer is formed on a surface of the first substrate, and a first copper layer is disposed within the first oxide layer. A second oxide layer is formed on a surface of the second substrate, and a second copper layer is disposed within the second oxide layer. The first copper layer and the second copper layer are formed through a copper damascene process. In the thermocompression chip bonding method, a copper CMP process is performed on the first copper layer and the second copper layer, respectively, such that excess copper at the top surfaces of the first copper layer and the second copper layer are removed to form dishing concaves. Thereafter, a part of the first oxide layer is removed to protrude the top surface of the first copper layer from the first oxide layer, and a part of the second oxide layer is removed to protrude the top surface of the second copper layer from the second oxide layer. Next, a non-metal or barrier CMP process is performed on the top surface of the first copper layer protruding from the first oxide layer and the top surface of the second copper layer protruding from the second oxide layer, respectively, so as to change the top surfaces of the first and second copper layers into convexes. The non-metal or barrier CMP process is a copper passivation process. The convexes of the first and second copper layers are then bonded.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic sectional view of a chip bonding structure according to a first embodiment of the disclosure.

FIG. 2 is a schematic sectional view of a chip bonding structure according to a second embodiment of the disclosure.

FIG. 3A to FIG. 3E are schematic sectional views of a manufacturing process of a hybrid chip bond according to a third embodiment of the disclosure.

FIG. 4A to FIG. 4D are schematic sectional views of a manufacturing process of a thermocompression chip bond according to a fourth embodiment of the disclosure.

FIG. 5 is a curve of the relationship between a polishing pressure and a concave depth in a first experiment example.

FIG. 6A to FIG. 6C are the topographies of a copper bond pad after all steps in a second experiment example.

FIG. 7 is the topography of a copper bond pad at different regions of a 12-inch wafer in a third experiment example.

FIG. 8A is a schematic view of a copper bond pad-copper bond pad bond according to a fifth embodiment of the disclosure.

FIG. 8B is a schematic view of a copper through-silicon via (TSV)-copper TSV bond according to a sixth embodiment of the disclosure.

FIG. 8C is a schematic view of a copper bond pad-copper TSV bond according to a seventh embodiment of the disclosure.

### DETAILED DESCRIPTION OF DISCLOSED EMBODIMENTS

In the drawings of the disclosure, for clarification, the sizes and relative sizes of layers and regions may be exaggerated. Also, when a device or layer is referred to as “on another element or layer”, the element or layer may be directly on another element or layer, or an intermediate element or layer may exist therebetween. In addition, although “first”, “second”, and the like are used to describe elements, layers or parts in the disclosure, “first”, “second”, and the like are only used for distinguishing a device, layer or part from another region, layer or part. Therefore, without departing from the teachings of the disclosure, the first element, layer or part and the second element, layer or part are interchangeable.

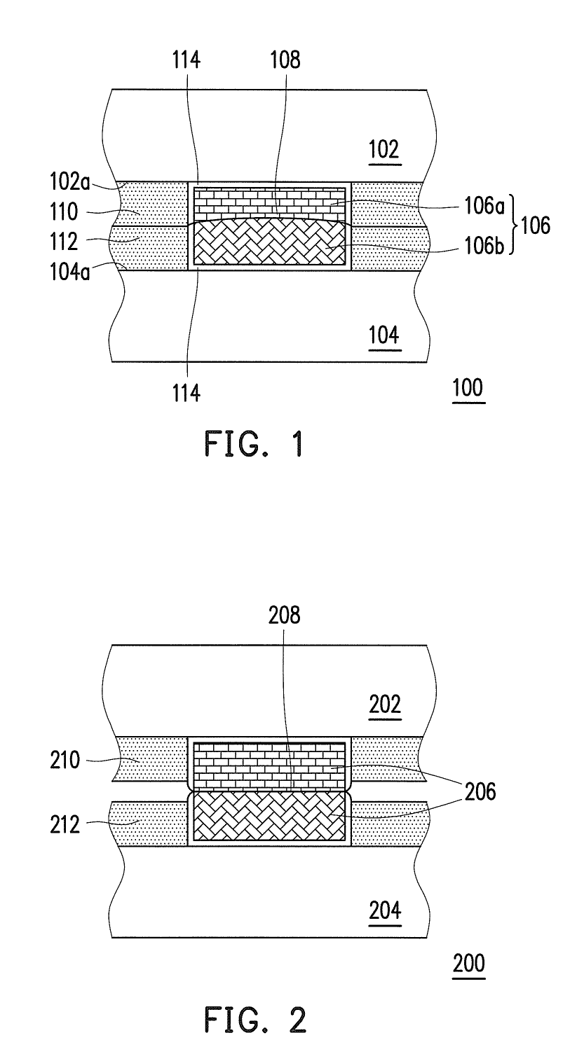

FIG. 1 is a schematic sectional view of a chip bonding structure according to a first embodiment of the disclosure.

Please refer to FIG. 1, a chip bonding structure 100 in the first embodiment at least comprises a first substrate 102, a second substrate 104 opposite to the first substrate 102, and a copper bonding structure 106 sandwiched in between the first substrate 102 and the second substrate 104. The copper bonding structure 106 is basically obtained by bonding two copper bond pads 106a and 106b, a Cu—Cu bonding interface 108 is within the copper bonding structure 106 and is characterized with combinations of protrusions and recesses, and the copper crystallization orientation at one side of the Cu—Cu bonding interface 108 is different from that at another side.

In the first embodiment, the chip bonding structure 100 further comprises a first oxide layer 110 and a second oxide layer 112. The first oxide layer 110 is at a surface 102a of the first substrate 102, the second oxide layer 112 is at a surface 104a of the second substrate 104 (opposite to the first substrate 102), and the copper bonding structure 106 is inserted within the first oxide layer 110 and the second oxide layer 112. Moreover, a barrier layer 114 is disposed between the copper bonding structure 106 and a peripheral structure thereof (for example, oxide layers 110, 112 and substrates 102, 104). The first oxide layer 110 and the second oxide layer 112 may contact each other and be bonded through a covalent bond. In the first embodiment, the Cu—Cu bonding interface 108 is a concave-convex bonding surface, for example.

FIG. 2 is a schematic sectional view of a chip bonding structure according to a second embodiment of the disclosure.

Please refer to FIG. 2, a chip bonding structure 200 in the second embodiment, similar to the first embodiment, at least comprises a first substrate 202, a second substrate 204 opposite to the first substrate 202, and a copper bonding structure 206 sandwiched in between the first substrate 202 and the second substrate 204. A Cu—Cu bonding interface 208 is within the copper bonding structure 206 and is characterized with combinations of protrusions and recesses, and the copper crystallization orientation at one side of the Cu—Cu bonding interface 208 is different from that at another side. In addition, the chip bonding structure 200 further comprises a first oxide layer 210 and a second oxide layer 212, in which the difference between the second embodiment and the first embodiment lies in that the first oxide layer 210 and the second oxide layer 212 are apart from each other; that is to say, in this embodiment, the first oxide layer 210 and the second oxide layer 212 do not contact each other. In the second embodiment, Cu—Cu bonding interface 208 is a convex-convex bonding surface.

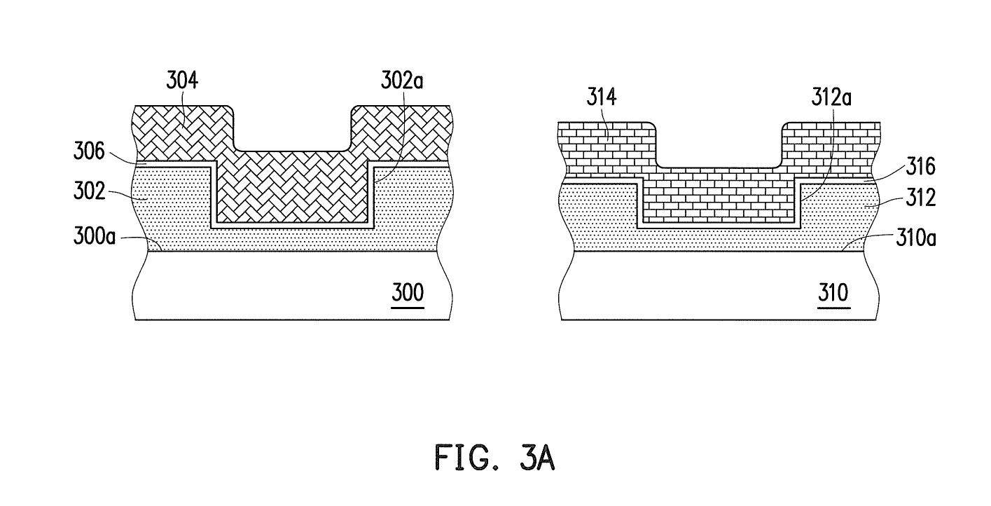

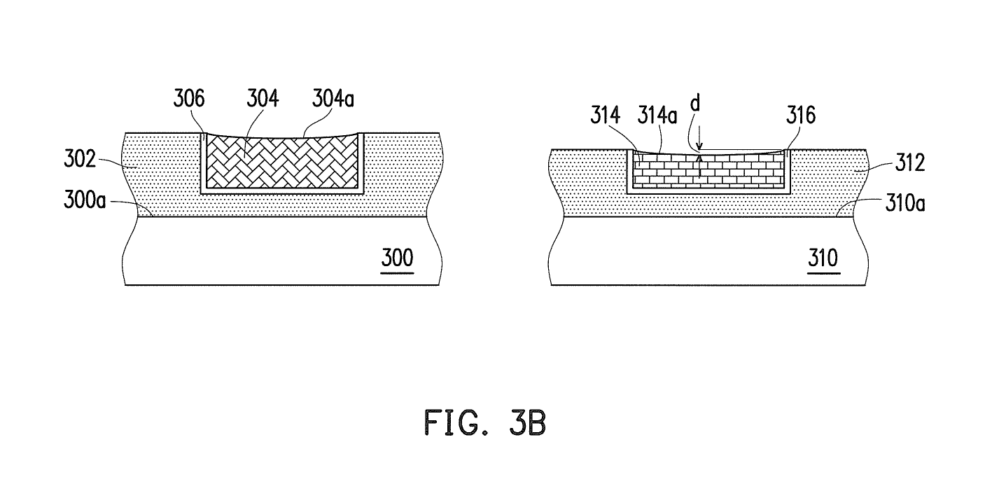

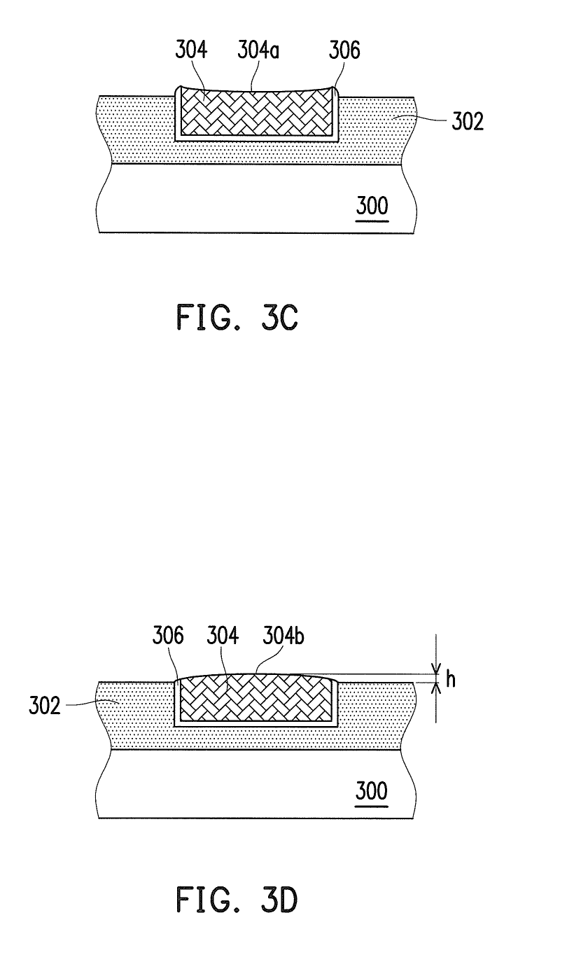

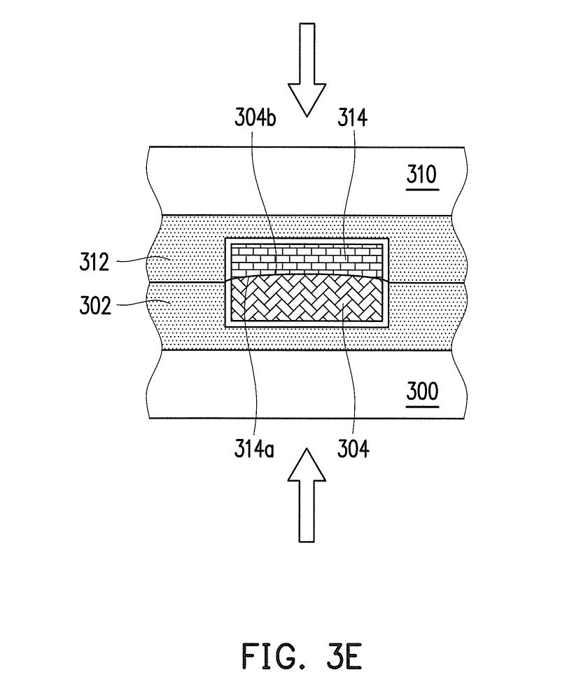

FIG. 3A to FIG. 3E are schematic sectional views of a manufacturing process of a hybrid chip bond according to a third embodiment of the disclosure.

Please refer to FIG. 3A first, the process in the third embodiment is integrated with the copper damascene manufacturing process. First, a first oxide layer 302 is formed on a surface 300a of a substrate 300, and the first oxide layer 302 comprises an opening 302a. A copper layer 304 is then plated on the surface 300a of the substrate 300 to cover the opening 302a of the first oxide layer 302. A barrier layer 306 is usually sandwiched in between the copper layer 304 and the first oxide layer 302. For another substrate 310, similarly, a second oxide layer 312 is formed on a surface 310a of the substrate 310, and the second oxide layer 312 comprises an opening 312a. Another copper layer 314 is then plated on the surface 310a of the substrate 310 to cover the opening 312a of the second oxide layer 312. Also a barrier layer 316 is usually sandwiched in between the copper layer 314 and the second oxide layer 312.

Subsequently, please refer to FIG. 3B, a first copper CMP process is performed on the first copper layer 304 to remove excess copper on the top surface of the first copper layer 304 to form a dishing concave 304a. At the same time, a second copper CMP process may also be performed on the second copper layer 314 to remove excess copper on the top surface of the second copper layer 314 to form a dishing concave 314a. In this embodiment, it is possible that some process parameters in the first copper CMP process and the second copper CMP process are different; however, the disclosure is not limited thereto.

As this embodiment is a hybrid bond, to match the bond between the first oxide layer 302 and the second oxide layer 312, a concave-convex bond is required for an interface between the first copper layer 304 and the second copper layer 314. Therefore, the topography of the interface between the first copper layer 304 and the second copper layer 314 needs to be controlled. For example, if the size (diameter or side length) of the second copper layer 314 is between 5 μm and 100 μm, the depth d at the center of the dishing concave 314a should be controlled between 50 Å and 4000 Å. As for how to control the depth d at the center of the dishing concave 314a, the depth of the dishing concave 314a is capable of being controlled by adjusting the parameter of the CMP process, for example, by changing a polishing pressure, or changing a polishing slurry, or selecting a polishing pad of a different material. Additional steps need to be performed on the first copper layer 304 to turn the dishing concave 304a into a convex.

Next, please refer to FIG. 3C, a part of the first oxide layer 302 is removed to protrude the top surface (that is, the dishing concave 304a) of the first copper layer 304 from the first oxide layer 302. In this embodiment, the method for removing a part of the first oxide layer 302 may adopt dry etching or wet etching. In detail, the etch rate selectivity for different materials in dry etching or the solubility selectivity for oxide and copper of wet etching solution are both capable of making the top surface of the copper layer 304 protrude from the first oxide layer 302. By taking wet etching as an example, a solution containing 0.1% to 49% hydrofluoric acid or an alkaline solution with pH>9 may be adopted to perform etching, and the etching time is, for example, between 5 seconds and 60 minutes.

Next, please refer to FIG. 3D, a non-metal or barrier CMP process is performed on the top surface of the first copper layer 304 protruding from the first oxide layer 302 to turn the top surface of the first copper layer 304 into a convex 304b. The so-called “non-metal or barrier CMP process” refers to a copper passivation CMP process, that is, a CMP process in which the polishing rate of copper is smaller than that of the non-metal or barrier layer, for example, an oxide CMP process or a barrier CMP process. The time of the non-metal or barrier CMP process is, for example, between 5 seconds and 20 minutes; however, the disclosure is not limited thereto. By performing the non-metal or barrier CMP process, the height h at the center of the convex 304b is able to be controlled, so as to match the topography of the dishing concave 314a of the second copper layer 314. For example, when the size (diameter or side length) of the first copper layer 304 is between 5 μm and 100 μm, the height h at the center of the convex 304b is controlled above 50 Å, for example, between 50 Å and 4000 Å.

Thereafter, please refer to FIG. 3E, the dishing concave 314a of the second copper layer 314 is connected to the convex 304b of the first copper layer 304, and at the same time the first and second oxide layers 302 and 312 contact each other. Next, an annealing is performed at the temperature, for example, between 200° C. and 600° C., so as to bond the first and second oxide layers 302 and 312 through a covalent bond formed therebetween, and bond the first copper layer 304 and the second copper layer 314 at the same time.

Since the first and second oxide layers 302 and 312 directly contact each other in the third embodiment, it is possible to make an oxide-oxide bond. Furthermore, due to the structure in the third embodiment, copper is provided with desirable contact to generate a bond between copper bond pads (Cu—Cu bond) during subsequent annealing process.

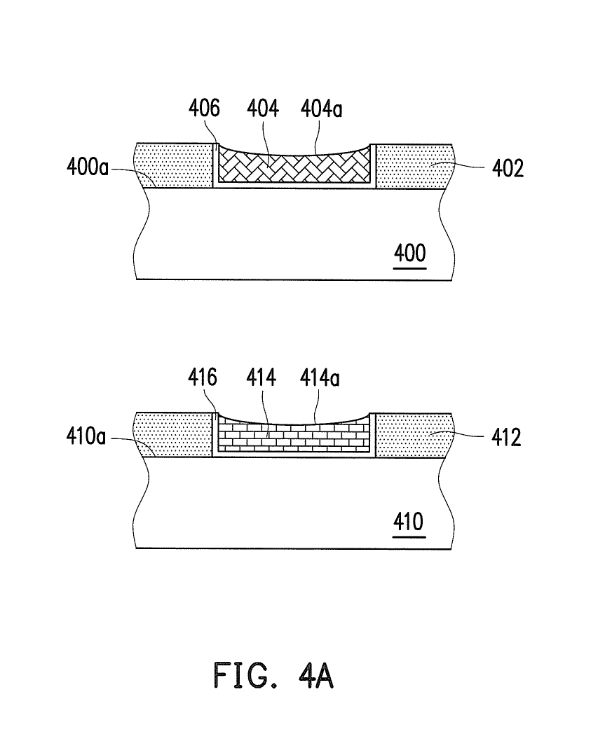

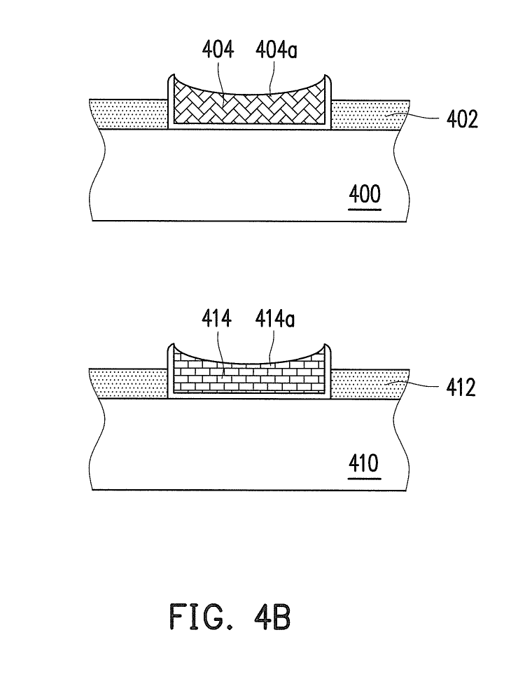

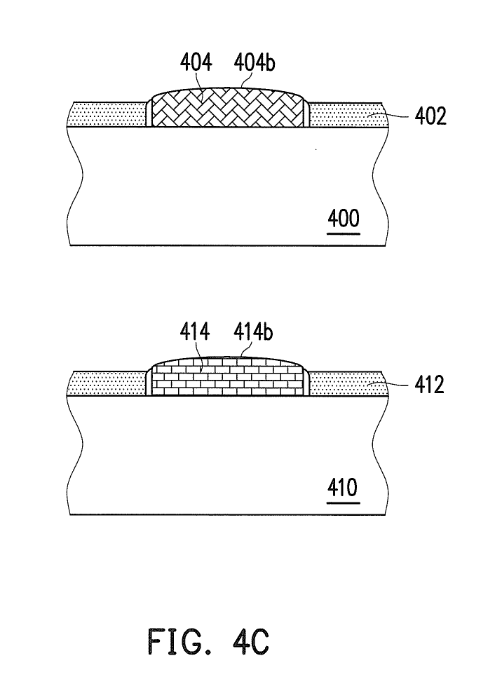

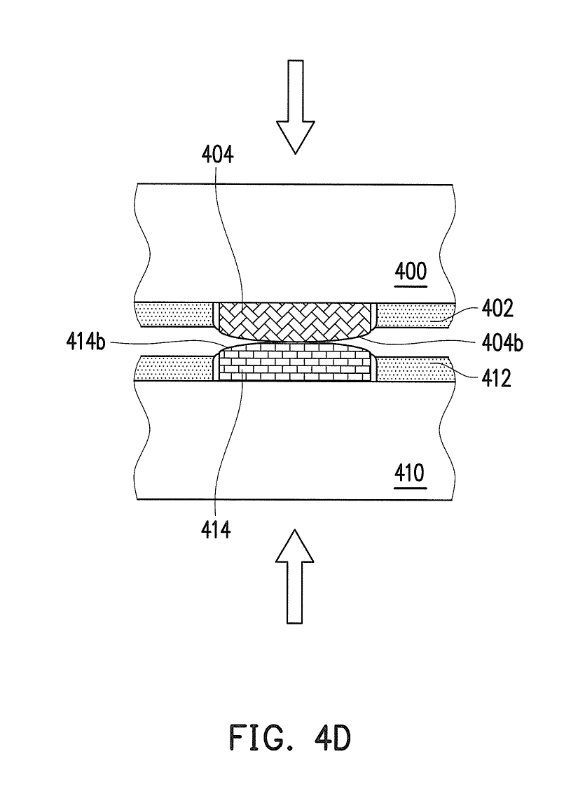

FIG. 4A to FIG. 4D are schematic sectional views of a manufacturing process of a thermocompression chip bond according to a fourth embodiment of the disclosure.

Please refer to FIG. 4A first, a first oxide layer 402 has been formed on a surface 400a of a substrate 400, and a first copper layer 404 is disposed within the first oxide layer 402. A second oxide layer 412 has been formed on a surface 410a of another substrate 410, and a second copper layer 414 is disposed within the second oxide layer 412. A barrier layer 406 is usually disposed between the first copper layer 404 and a peripheral structure thereof (for example, the first oxide layer 402 and the substrate 400). A barrier layer 416 is disposed between the second copper layer 414 and a peripheral structure thereof. First, in a copper damascene manufacturing process, a copper CMP process is performed on the first copper layer 404 and the second copper layer 414, respectively, and thus excess copper at the top surfaces of the first copper layer 404 and the second copper layer 414 are removed to form dishing concaves 404a and 414a.

Next, please refer to FIG. 4B, a part of the first oxide layer 402 is removed to protrude at least a part of the top surface of the first copper layer 404 from the first oxide layer 402, and a part of the second oxide layer 412 is removed to protrude at least a part of the top surface of the second copper layer 414 from the second oxide layer 412. In this embodiment, the method for removing the part of the first oxide layer 402 and the second oxide layer 412 is, for example, dry etching or wet etching. By taking wet etching as an example, a solution containing 0.1% to 49% hydrofluoric acid or an alkaline solution with pH>9 may be used to perform etching, and the etching time is, for example, between 5 seconds and 60 minutes.

Subsequently, please refer to FIG. 4C. A non-metal or barrier CMP process is performed on the top surfaces of the first copper layer 404 and the second copper layer 414, respectively, to turn the dishing concaves 404a and 414a into convexes 404b and 414b. The non-metal or barrier CMP process is, as defined in the third embodiment, a CMP process in which the polishing rate of copper is smaller than that of the non-metal or barrier layer. For example, the non-metal or barrier CMP process may be Oxide CMP or Barrier CMP. The time of the non-metal or barrier CMP process is, for example, between 5 seconds and 20 minutes. Through above step, a large part of copper oxide on the top surfaces of the first copper layer 404 and the second copper layer 414 are able to be removed.

Next, please refer to FIG. 4D, the convexes 404b and 414b of the first copper layer 404 and the second copper layer 414 are bonded by performing, for example, a thermocompression bonding at the temperature between 200° C. and 600° C. Here, the first oxide layer 402 and the second oxide layer 412 are apart from each other. The conductivity of the bonding structure may be enhanced because the metal oxide layers at the surfaces of the first copper layer 404 and the second copper layer 414 have been removed in the preceding step.

The implementation of the exemplary embodiments of the disclosure is proved by following experiment examples.

### First Experiment Example

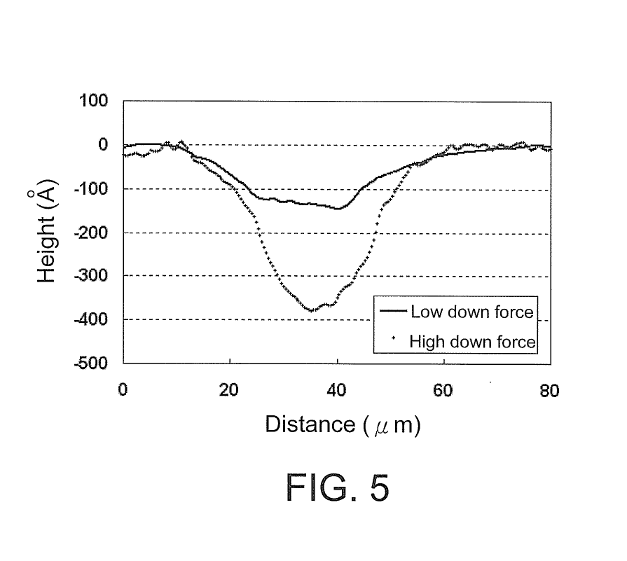

The polishing pressure in a copper CMP process is changed to perform polishing on the same copper layer, respectively to obtain copper bond pads. Subsequently, the KLA Tencor HRP340 is utilized to scan chip surface, and the results are shown in FIG. 5. As can be seen from FIG. 5, when the polishing pressure is larger, the dishing concave is deeper, and when the polishing pressure is smaller, the dishing concave is shallower.

### Second Experiment Example

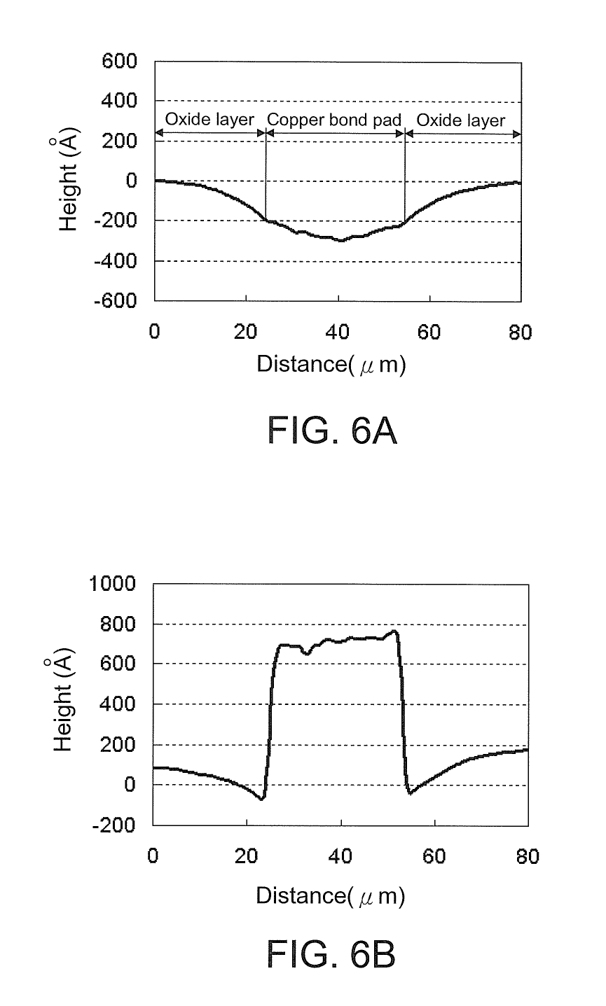

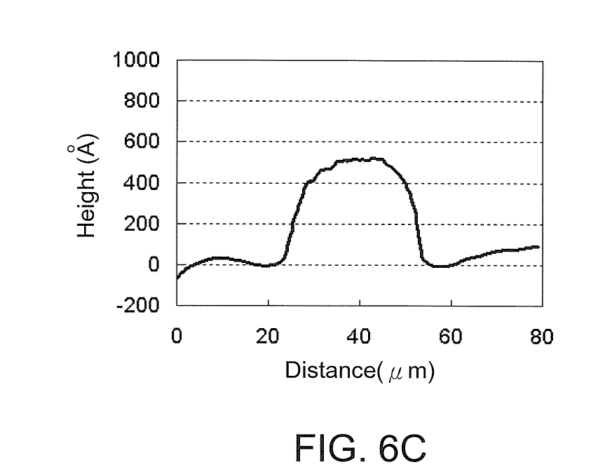

First, after the copper CMP process, the KLA Tencor HRP340 is utilized to scan chip surface, and the results are shown in FIG. 6A. FIG. 6A is the topography of the copper bond pad after the copper CMP process in a copper damascene manufacturing process, and a dishing concave is presented at the surface of the copper bond pad.

Subsequently, a wet etching solution is used to etch the oxide layer, the KLA Tencor HRP340 is further used to scan chip surface, and the topography result thereof is shown in FIG. 6B. As can be seen FIG. 6B, it can be observed that the topography of the copper bond pad is a dishing cylinder at the upper surface, and the height of the cylinder may meet the demand by controlling process parameters.

Next, the topography of the dishing cylinder is modified through a Barrier CMP, and the KLA Tencor HRP340 is used to scan chip surface, and the results are shown in FIG. 6C. As can be seen from FIG. 6C, it can be observed that a semi-elliptical convex is presented at the surface of the copper bond pad.

### Third Experiment Example

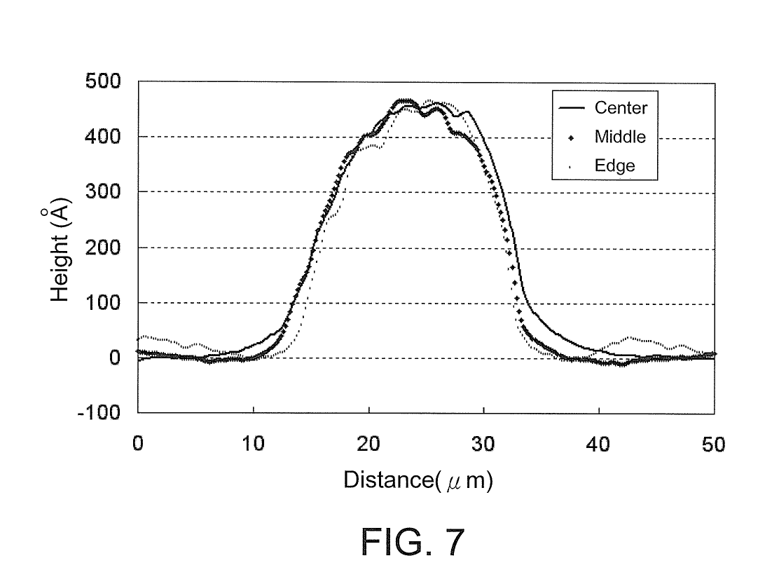

By taking a copper bond pad with the diameter of 20 μm as an example, the copper bond pad in the second experiment example is manufactured at different regions on a 12-inch wafer, and the KLA Tencor HRP340 is used to scan wafer surface, and the results are shown in FIG. 7. As can be seen from FIG. 7, the topographies of the copper bond pads at the center, edge, and middle of the 12-inch wafer are similar.

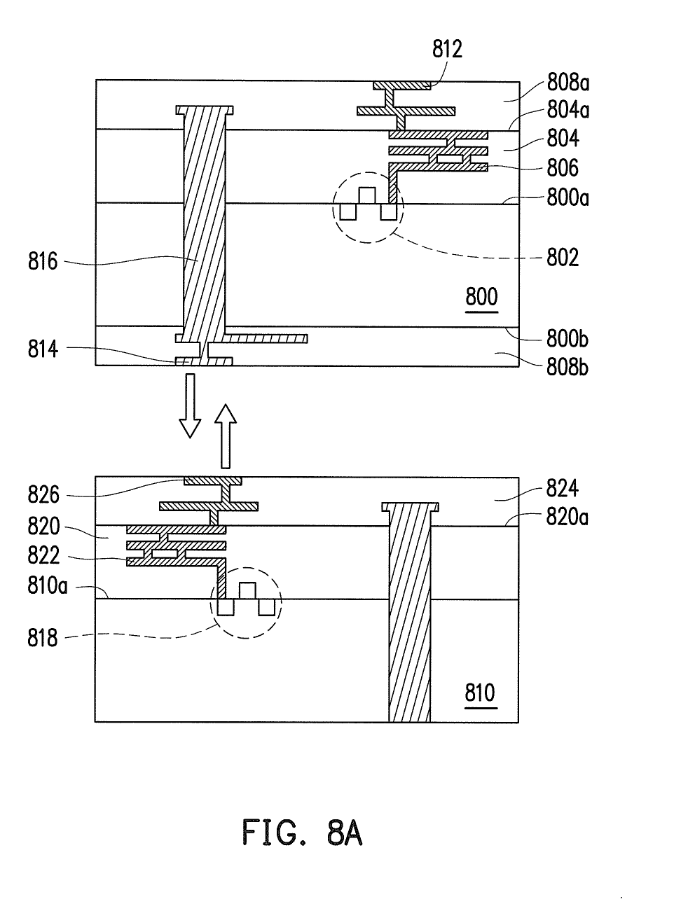

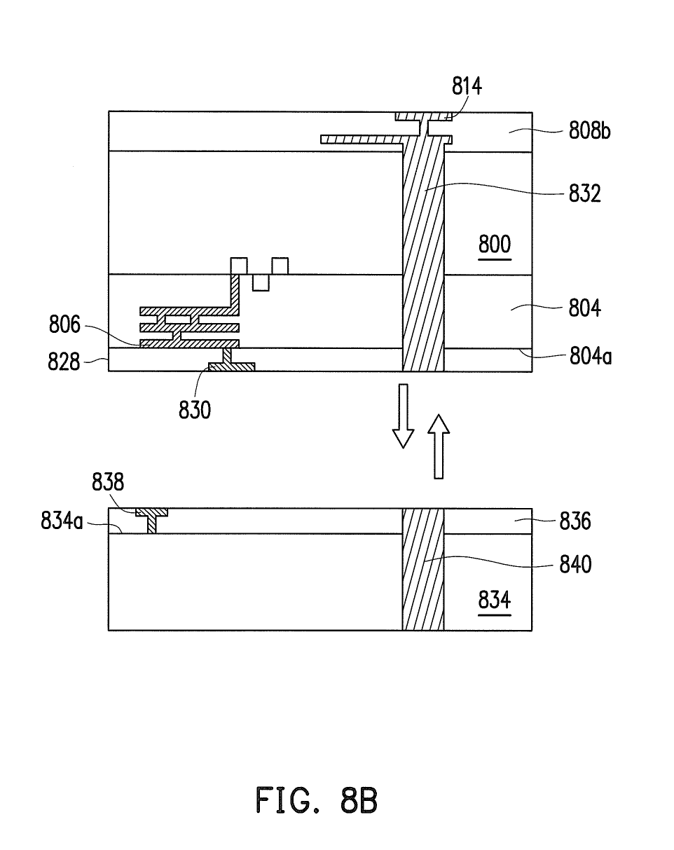

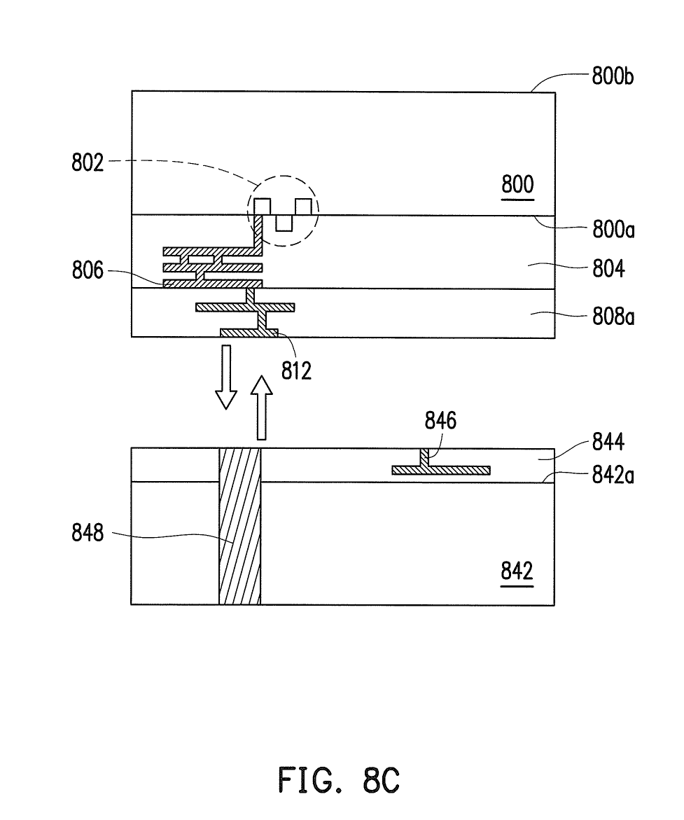

FIG. 8A to FIG. 8C are schematic views, a carrier might be used for assistance in the manufacturing process; however, the disclosure is not limited thereto.

FIG. 8A is a schematic view of a copper bond pad-copper bond pad bond according to a fifth embodiment of the disclosure.

Please refer to FIG. 8A, as a whole, the chip bond in the disclosure may be a copper bond pad-copper bond pad bond of a Re-distribution Layer (RDL). In FIG. 8A, two substrates 800 and 810 are shown. For example, a device 802 is formed in the substrate 800, an inter metal (IM) layer 806 is formed in a dielectric layer 804 on a surface 800a of the substrate 800, a RDL 812 is formed in a dielectric layer 808a on a surface 804a of the dielectric layer 804, and another RDL 814 is formed within a dielectric layer 808b on another surface 800b of the substrate 800. In addition, a through-silicon via (TSV) 816 is formed therein. Another substrate 810 may also comprise a device 818 and a dielectric layer 820 and an IM layer 822 on a surface 810a thereof. A RDL 826 is formed within the dielectric layer 824 on a surface 820a of the dielectric layer 820.

In this embodiment, the copper bond pad of the RDL 814 is bonded to the copper bond pad of the RDL 826. Moreover, the RDLs 814 and 826 in FIG. 8A may be a front-side RDL, a backside RDL, a front-side RDL of an interposer, or a backside RDL of an interposer. In other words, in FIG. 8A, the bond between the copper bond pad of the RDL 814 and the copper bond pad of the RDL 826 may be that a front-side RDL copper bond pad (comprising an interposer) is bonded to a front-side RDL copper bond pad (comprising an interposer) or bonded to a backside RDL copper bond pad (comprising an interposer), or may also be that a backside RDL copper bond pad (comprising an interposer) is bonded to a backside RDL copper bond pad (comprising an interposer).

FIG. 8B is a schematic view of a copper TSV-copper TSV bond according to a sixth embodiment of the disclosure, in which the same symbols of elements in the fifth embodiment are used to represent the same or similar members.

Please refer to FIG. 8B, in the substrate 800, a TSV 832 is connected to an RDL 814, and a RDL 830 is formed within a dielectric layer 828 on the surface 804a of the dielectric layer 804. A RDL 838 is formed within a dielectric layer 836 on a surface 834a of another substrate 834, and another TSV 840 is formed therein. The TSVs 832 and 840 may be manufactured through the following process: front-side via-last process, front-side via-middle process, front-side via-first process, or backside via-last process. The so-called “front-side via-last process” is a TSV process after manufacturing the device and metal interconnection at front-side of a wafer. The so-called “front-side via-middle process” is a TSV process after manufacturing the device and before manufacturing metal interconnection at front-side of a wafer. The so-called “front-side via-first process” is a TSV process before manufacturing the device at the front-side of a wafer. The so-called “backside via-last process” is a TSV process on a backside of the wafer after the thinning toward the backside. The TSVs 832 and 840 may also be interposer TSVs.

In this embodiment, the TSVs 832 and 840 may be that a front-side TSV (comprising an interposer) is bonded to a front-side TSV (comprising an interposer) through a front-side or a backside, or a front-side TSV (comprising an interposer) is bonded to a backside TSV (comprising an interposer) through a front-side or backside, or a backside TSV (comprising an interposer) is bonded to a backside TSV (comprising an interposer).

FIG. 8C is a schematic view of a copper bond pad-TSV bond according to a seventh embodiment of the disclosure, in which the same symbols of elements in the fifth embodiment are used to represent the same or similar members.

Please refer to FIG. 8C, the RDL 812 within the dielectric layer 808a is opposite to a TSV 848 within another substrate 842, and a RDL 846 is formed in a dielectric layer 844 on a surface 842a of a substrate 842. The RDL 812 and the TSV 848 in this embodiment may be referred to the fifth and sixth embodiments; that is to say, the copper bond pad of the RDL 812 and the TSV 848 may be that a front-side TSV (comprising an interposer) is bonded to a front-side RDL copper bond pad (comprising an interposer) through a front-side or a backside, or a front-side TSV (comprising an interposer) is bonded to a backside RDL copper bond pad (comprising an interposer) through a front-side or a backside, or a backside TSV is bonded to a front-side RDL copper bond pad (comprising an interposer), or a backside TSV is bonded to a backside RDL copper bond pad (comprising an interposer).

To sum up, the method proposed in the disclosure is capable of performing bonding with a primary copper layer directly without additional steps (such as electroplating, electroless plating, substitution, deposition) to form a metal layer for bonding, and the method of the disclosure may be directly applied to a copper bond pad-copper bond pad bond or a TSV-TSV bond or a copper bond pad-TSV bond.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A chip bonding structure, at least comprising:
a first substrate;
a second substrate, opposite to the first substrate; and
a copper bonding structure, sandwiched in between the first substrate and the second substrate, a Cu—Cu bonding interface is within the copper bonding structure and is characterized with combinations of protrusions and recesses, and a copper crystallization orientation at one side of the Cu—Cu bonding interface is different from that at another side of the Cu—Cu bonding interface.

2. The chip bonding structure according to claim 1, wherein the Cu—Cu bonding interface is a concave-convex bonding surface or a convex-convex bonding surface.

3. The chip bonding structure according to claim 1, further comprising:
a first oxide layer, at a surface of the first substrate; and
a second oxide layer, at a surface of the second substrate opposite to the first substrate, wherein the copper bonding structure is inserted within the first oxide layer and the second oxide layer.

4. The chip bonding structure according to claim 3, wherein the first oxide layer and the second oxide layer are apart from each other.

5. The chip bonding structure according to claim 3, wherein the first oxide layer and the second oxide layer contact each other.

6. The chip bonding structure according to claim 5, wherein the first oxide layer and the second oxide layer are bonded through a covalent bond formed therebetween.

7. A hybrid chip bonding method, for bonding a first substrate and a second substrate, wherein a first oxide layer is formed on a surface of the first substrate and a first copper layer is within the first oxide layer, a second oxide layer is formed on a surface of the second substrate and a second copper layer is within the second oxide layer, and the first copper layer and the second copper layer are formed through a copper damascene process, and the method comprising:
performing a first copper chemical mechanical polishing (CMP) process on the first copper layer such that excess copper at a top surface of the first copper layer is removed to form a dishing concave;
performing a second copper CMP process on the second copper layer such that excess copper at a top surface of the second copper layer is removed to form a dishing concave;
removing a part of the first oxide layer to protrude the top surface of the first copper layer from the first oxide layer;
performing a non-metal or barrier CMP process on the top surface of the first copper layer protruding from the first oxide layer to turn the top surface of the first copper layer into a convex, wherein the non-metal or barrier CMP process is a CMP process in which a polishing rate of copper is slower than that of a non-metal or barrier layer;
connecting the dishing concave of the second copper layer to the convex of the first copper layer, and making the first oxide layer and the second oxide layer contact each other simultaneously; and
performing an annealing to bond the first oxide layer and the second oxide layer via a covalent bond formed therebetween and bond the first copper layer and the second copper layer at the same time.

8. The hybrid chip bonding method according to claim 7, wherein the second copper layer comprises a copper bond pad or a copper through-silicon via (TSV), a size, side length or diameter, of the copper bond pad or the copper TSV is between 5 μm and 100 μm, and a depth at a center of the dishing concave is controlled between 50 Å and 4000 Å.

9. The hybrid chip bonding method according to claim 7, wherein the first copper layer comprises a copper bond pad or a copper through-silicon via (TSV), a size, side length or diameter, of the copper bond pad or the copper TSV is between 5 μm and 100 μm, and a height at a center of the convex is controlled above 50 Å.

10. The hybrid chip bonding method according to claim 7, wherein a method for removing the part of the first oxide layer comprises dry etching or wet etching.

11. The hybrid chip bonding method according to claim 10, wherein a solution of the wet etching is the solution containing 0.1% to 49% hydrofluoric acid or an alkaline solution with pH>9.

12. The hybrid chip bonding method according to claim 11, wherein an etching time of the wet etching is between 5 seconds and 60 minutes.

13. The hybrid chip bonding method according to claim 7, wherein a time of the non-metal or barrier CMP process is between 5 seconds and 20 minutes.

14. A thermocompression chip bonding method, for bonding a first substrate and a second substrate, wherein a first oxide layer is formed on a surface of first substrate and a first copper layer is within the first oxide layer, a second oxide layer is formed on a surface of second substrate and a second copper layer is within the second oxide layer, and the first copper layer and the second copper layer are formed through a copper damascene process, and the method comprising:
performing a copper chemical mechanical polishing (CMP) process on the first copper layer and the second copper layer, respectively, such that excess copper at top surfaces of the first copper layer and the second copper layer are moved to form dishing concaves;
removing a part of the first oxide layer to protrude the top surface of the first copper layer from the first oxide layer;
removing a part of the second oxide layer to protrude the top surface of the second copper layer from the second oxide layer;
performing a non-metal or barrier CMP process on the top surface of the first copper layer protruding from the first oxide layer and the top surface of the second copper layer protruding from the second oxide layer, respectively, so as to turn the dishing concaves of the first copper layer and the second copper layer into convexes, wherein the non-metal or barrier CMP process is a CMP process in which a polishing rate of copper is slower than that of a non-metal or barrier layer; and
bonding the convexes of the first copper layer and the second copper layer.

15. The thermocompression chip bonding method according to claim 14, wherein a method for bonding the convexes of the first copper layer and the second copper layer comprises performing a thermocompression bonding at a temperature between 200° C. and 600° C.

16. The thermocompression chip bonding method according to claim 14, wherein a method for removing the part of the first oxide layer and removing the part of the second oxide layer comprises dry etching or wet etching.

17. The thermocompression chip bonding method according to claim 16, wherein a solution of the wet etching is the solution containing 0.1% to 49% hydrofluoric acid or an alkaline solution with pH>9.

18. The thermocompression chip bonding method according to claim 17, wherein an etching time of the wet etching is between 5 seconds and 60 minutes.

19. The thermocompression chip bonding method according to claim 14, wherein a time of the non-metal or barrier CMP process is between 5 seconds and 20 minutes.
